(19) United States
(12) Patent Application Publication
(10) Pub. No.: US 2025/0218783 A1
(43) Pub. Date: Jul. 3, 2025

(54) METHOD, SYSTEM AND APPARATUS FOR FORMING A THRESHOLD VOLTAGE SHIFTING LAYER

(71) Applicant: ASM IP Holding B.V., Almere (NL)

(72) Inventors: Giuseppe Alessio Verni, Ismaning (DE); Suvidyakumar Vinod Homkar, Leuven Flanders (BE); Vivek Koladi Mootheri, Leuven (BE); Ren-Jie Chang, Chandler, AZ (US); Michael Eugene Givens, Oud-Heverlee (BE); Patricio Romero, Wilsele (BE); Charles Dezelah, Helsinki (FI); Fu Tang, Gilbert, AZ (US); Eric James Shero, Phoenix, AZ (US)

(21) Appl. No.: 19/005,068

(22) Filed: Dec. 30, 2024

Related U.S. Application Data
(60) Provisional application No. 63/617,002, filed on Jan. 2, 2024.

(51) Int. Cl. H01L 21/285; C23C 16/44; C23C 16/455

(52) U.S. Cl. CPC H01L 21/28568; C23C 16/4408; C23C 16/45553

(57) ABSTRACT

A method comprising depositing a threshold voltage shifting layer on a substrate, wherein the layer comprises a metal and has the formula M(NxCyOz), wherein M is a metal, N is nitrogen, C is carbon, and O is oxygen, wherein x=0 to 5, y=0 to 5, z=0 to (x+y), wherein (x+y)≥0.1, wherein depositing the threshold voltage shifting layer further comprises one or more of the following operations: providing the substrate having a surface within a reaction chamber; providing a metal-containing precursor comprising the metal to the reaction chamber to contact the surface; providing one or more additional precursors comprising at least one of N or C to the reaction chamber to contact the surface; and/or purging the reaction chamber; and repeating one or more of the disclosed operations or any combination thereof in any order until the threshold voltage shifting layer of a predetermined thickness is deposited on the surface.

### CROSS-REFERENCE TO RELATED APPLICATIONS

This application claims priority to U.S. Provisional Patent Application Ser. No. 63/617,002 filed Jan. 2, 2024 titled METHOD, SYSTEM AND APPARATUS FOR FORMING A THRESHOLD VOLTAGE SHIFTING LAYER, the disclosure of which is hereby incorporated by reference in its entirety.

### FIELD OF THE DISCLOSURE

The present disclosure generally relates to the field of semiconductor processing methods, systems and apparatus, and to the field of electronic devices, and in particular, methods, systems and apparatus suitable for forming a threshold voltage shifting layer comprising a metal.

### BACKGROUND OF THE DISCLOSURE

The scaling of semiconductor devices, such as, complementary metal-oxide-semiconductor (CMOS) devices, has led to significant improvements in speed and density of integrated circuits. However, conventional device scaling techniques face significant challenges for future technology nodes.

For example, one challenge has been finding a suitable conducting material for use as a gate electrode, and particularly threshold voltage shift materials, in aggressively scaled CMOS devices. Therefore, improved materials for gate electrodes are desired. In particular, such materials can include threshold voltage shifting layers, and can be used for threshold voltage tuning.

### SUMMARY OF THE DISCLOSURE

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

In one aspect, a method for depositing a threshold voltage shifting layer on a substrate is disclosed, wherein the layer comprises a metal and has the formula M(NxCyOz), wherein M is a metal, N is nitrogen, C is carbon, and O is oxygen, wherein x=0 to 5, y=0 to 5, z=0 to (x+y), wherein (x+y)≥0.1. In an example, depositing the threshold voltage shifting layer may further comprise providing the substrate having a surface within a reaction chamber; providing a metal-containing precursor comprising the metal to the reaction chamber to contact the surface; providing one or more additional precursors comprising at least one of N or C to the reaction chamber to contact the surface; purging the reaction chamber; and/or repeating the above operations in any combination, in any order until the threshold voltage shifting layer of a predetermined thickness is deposited on the surface. The method may include wherein x=0 to 2 and y=0 to 2 and wherein (x+y)≥1, or the method may include wherein (x+y)≥1.

In some embodiments, the method may include wherein at least one of the one or more additional precursors comprises O.

In certain examples, the method may include wherein the surface comprises an interlayer material and the threshold voltage shifting layer is deposited in a dipole first pattern directly onto the interlayer material surface.

In various examples, the method may include wherein the surface comprises a high-k material and the threshold voltage shifting layer is deposited in a dipole last pattern directly onto the high-k material surface.

In some embodiments, the method may include wherein the metal comprises cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), titanium (Ti), zirconium (Zr), hafnium (Hf), tantalum (Ta), scandium (Sc), lutetium (Lu), yttrium (Y), magnesium (Mg), lanthanum (La), or strontium (Sr), or a combination thereof.

In particular examples, the method may include wherein the metal-containing precursor comprises a cyclopentadienyl ligand.

In various examples, the method may include wherein the cyclopentadienyl ligand comprises at least one of cyclopentadienyl (Cp), methylcyclopentadienyl (MeCp), ethylcyclopentadienyl (EtCp), isopropylcyclopentadienyl (iPrCp), tert-butylcyclopentadienyl (tBuCp), trimethylsilylcyclopentadienyl (TMSCp), pentamethylcyclopentadientyl (Cp*), 1,2,4-triisopropylcyclopentadienyl (iPr₃Cp), and 1,2,4-tri-tert-butylcyclopentadienyl (tBu₃Cp).

In certain examples, the method may include wherein the metal-containing precursor comprises an amido ligand.

In some embodiments, the method may include wherein the amido ligand comprises at least one of dimethylamido (NMe₂), diethylamido (NEt₂), ethylmethylamido (NEtMe), diisopropylamido (NiPr₂), tert-butylamino (NHtBu), and bis(trimethylsilyl)amido (N(SiMe₃)₂).

In particular examples, the method may include wherein the metal-containing precursor comprises an imido ligand.

In various examples, the method may include wherein the imido ligand comprises at least one of ethylimido (NEt), isoproptylimido (NiPr), isobutylimido (NiBu), tert-butylimido (NtBu), and tert-pentylimido (NtPn).

In examples, the method may include wherein the metal-containing precursor comprises an amidinate ligand.

In certain examples, the method may include wherein the amidinate ligand comprises at least one of N,N′-diethylacetamidinate (Et₂AMD), N,N′-diisopropylacetamidinate (iPr₂AMD), N,N′-diisopropylformamidinate (iPr₂FMD), N,N′-di-tert-butylacetamidinate (tBu₂AMD), and N,N′-di-tert-butylformamidinate (tBu₂FMD).

In some embodiments, the method may include wherein the metal-containing precursor comprises a halogen ligand.

In particular examples, the method may include wherein the halogen ligand comprises, at least one of (F) fluorine, (Cl) chlorine, (Br) bromine or (I) iodine.

In some embodiments, the method may include wherein the metal-containing precursor comprises an alkyl ligand.

In various examples, the method may include wherein the alkyl ligand comprises, at least one of methyl (Me), ethyl (Et), isopropyl (iPr), tert-butyl (tBu), isobutyl (iBu), and neopentyl (Np).

In certain examples, the method may include wherein the metal-containing precursor comprises an alkoxide ligand.

In some embodiments, the method may include wherein the alkoxide ligand comprises, at least one of methoxide (OMe), ethoxide (OEt), isopropoxide (OiPr), tert-butoxide (OtBu), 1-methoxy-2-methyl-2-propoxide (mmp), 1-dimethylamino-2-propoxide (dmap), 1-dimethylamino-2-methyl-2-propoxide (dmamp), and 1-dimethylamino-2-methyl-2-butoxide (dmamb).

In particular examples, the method may include wherein the metal-containing precursor comprises a diketonate ligand.

In various embodiments, the method may include wherein the diketonate ligand comprises, at least one of acetylacetonate (acac), 2,2,6,6-tetramethylheptane-3,5-dionate (thd), and 1,1,1,5,5,5-hexafluoropentane-2,5-dionate (hfac).

In various examples, the method may include wherein the metal-containing precursor comprises a diazabutadiene ligand.

In particular embodiments, the method the diazabutadiene ligand comprises, at least one of 1,4-di-tert-butyl-1,4-diaza-1,3-butadiene (tBu₂DAD), 1,4-diisopropyl-1,4-diaza-1,3-butadiene (iPr₂DAD), 1,4-di-sec-butyl-1,4-diaza-1,3-butadiene (sBu₂DAD) and 1,4-di-tert-pentyl-1,4-diaza-1,3-butadiene (tPn₂DAD).

In some embodiments, the method may include wherein at least one of the one or more additional precursors is a nitrogen-containing precursor.

In particular examples, the method may include wherein the nitrogen-containing precursor is selected from: ammonia, hydrazine, tert-butylhydrazine, dimethylhydrazine, methylhydrazine, phenylhydrazine, tert-butylamine, isobutylamine, tert-pentylamine, N₂ plasma, NH₃ plasma, or N₂/H₂ plasma, or any combination thereof.

In certain examples, the method may include wherein at least one of the one or more additional precursors is a carbon-containing precursor.

In various examples, the method may include wherein the carbon-containing precursor is selected from: iodomethane, diiodomethane, iodoethane, 1,2-diiodoethane, bromoethane, 1,2-dibromoethane, bromobenzene, iodobenzene, 1-iodobutane, dicyclopentadiene, acetylene, propargyl bromide, allyl bromide, or allyl iodide, or a combination thereof.

In some embodiments, the method may include wherein at least one of the one or more additional precursors is an oxygen-containing precursor.

In particular embodiments, the method may include wherein the oxygen-containing precursor is selected from: H₂O, ozone, N₂O, H₂O₂, O₂, or O₂ plasma, or any combination thereof.

In particular examples, the method may include wherein the metal comprises titanium (Ti) and wherein the metal-containing precursor comprises TiF₄, TiCl₄, TiBr₄, TiI₄, Ti(NMe₂)₄, Ti(NEtMe)₄, Ti(NEt₂)₄, Ti(OMe)₄, Ti(OEt)₄, Ti(OiPr)₄, Ti(OtBu)₄, Ti(MeCp)(OiPr)₃, TiCp*(OMe)₃, TiCp(NMe₂)₄, Ti(EtCp)(NMe₂)₄, Ti(OiPr)₂(NMe₂)₂, Ti(OiPr)₂(thd)₂, Ti(OiPr)₃(iPr₂AMD), or Ti(Np)₄, or a combination thereof.

In certain examples, the method may include wherein the metal comprises zirconium (Zr) and wherein the metal-containing precursor comprises ZrCl₄, ZrI₄, Zr(NMe₂)₄, Zr(NEtMe)₄, Zr(NEt₂)₄, Zr(thd)₄, Zr(OiPr)₄, Zr(OtBu)₄, ZrCp(NMe₂)₃, Zr(MeCp)(NMe₂)₃, Zr(EtCp)(NMe₂)₃, ZrCp(NEt₂)₃, Zr(MeCp)(NEt₂)₃, Zr(EtCp)(NEt₂)₃, ZrCp(NEtMe)₃, Zr(MeCp)(NEtMe)₃, Zr(EtCp)(NEtMe)₃, ZrCp₂Cl₂, ZrCp₂Me₂, ZrCp₂(OMe)₂, ZrCp₂Me(OMe), ZrCp₂(NMe₂)₂, Zr(MeCp)₂Cl₂, Zr(MeCp)₂Me₂, Zr(MeCp)₂(OMe)₂, Zr(MeCp)₂Me(OMe), Zr(MeCp)₂(NMe₂)₂, Zr(EtCp)₂Cl₂, Zr(EtCp)₂Me₂, Zr(EtCp)₂(OMe)₂, Zr(EtCp)₂Me(OMe), Zr(EtCp)₂(NMe₂)₂, ZrNp₄, or ZrCp(tBu₂DAD)(OiPr), or any combination thereof.

In various examples, the method may include wherein the metal comprises hafnium (Hf) and wherein the metal-containing precursor comprises HfCl₄, HfI₄, Hf(NMe₂)₄, Hf(NEtMe)₄, Hf(NEt₂)₄, Hf(thd)₄, Hf(OiPr)₄, Hf(OtBu)₄, Hf(BH₄)₄, HfCp(NMe₂)₃, Hf(MeCp)(NMe₂)₃, Hf(EtCp)(NMe₂)₃, HfCp(NEt₂)₃, Hf(MeCp)(NEt₂)₃, Hf(EtCp)(NEt₂)₃, HfCp(NEtMe)₃, Hf(MeCp)(NEtMe)₃, Hf(EtCp)(NEtMe)₃, HfCp₂Cl₂, HfCp₂Me₂, HfCp₂(OMe)₂, HfCp₂Me(OMe), HfCp₂(NMe₂)₂, Hf(MeCp)₂Cl₂, Hf(MeCp)₂Me₂, Hf(MeCp)₂(OMe)₂, Hf(MeCp)₂Me(OMe), Hf(MeCp)₂(NMe₂)₂, Hf(EtCp)₂Cl₂, Hf(EtCp)₂Me₂, Hf(EtCp)₂(OMe)₂, Hf(EtCp)₂Me(OMe), Hf(EtCp)₂(NMe₂)₂, Hf(MeCp)₂(mmp)Me, Hf(OtBu)₂(mmp)₂, Hf(iPr₂FMD)₂(NMe₂)₂, HfNp₄, Hf(dmap)₄, or Hf(mmp)₄, or any combination thereof.

In particular examples, the method may include wherein the metal comprises tantalum (Ta) and wherein the metal-containing precursor comprises TaF₅, TaCl₅, TaBr₅, TaI₅, Ta(NMe₂)₅, Ta(NEt₂)₅, Ta(NEtMe)₅, Ta(NtBu)(NMe₂)₃, Ta(NtBu)(NEt₂)₃, Ta(NtBu)(NEtMe)₃, Ta(NiPr)(NEtMe)₃, Ta(NtPn)(NMe₂)₃, Ta(OEt)₅, TaNp₃Cl₂, Ta(NtBu) Cl₃, Ta(NtPn) Cl₃, or Ta(NtBu)(iPr₂AMD)₂(NMe₂), or any combination thereof.

In some embodiments, the method may include wherein the metal comprises scandium (Sc) and wherein the metal-containing precursor comprises ScCp₃, Sc(MeCp)₃, Sc(EtCp)₃, Sc(iPrCp)₃, Sc(acac)₃, Sc(thd)₃, Sc(N(SiMe₃)₂)₃, Sc(Et₂AMD)₃, Sc(iPr₂FMD)₃, Sc(iPr₂AMD)₃, Sc(tBu₂FMD)₃, Sc(tBu₂AMD)₃, ScCp₂(iPr₂FMD), Sc(MeCp)₂(iPr₂FMD), Sc(EtCp)₂(iPr₂FMD), Sc(iPrCp)₂(iPr₂FMD), ScCp₂(iPr₂AMD), Sc(MeCp)₂(iPr₂AMD), Sc(EtCp)₂(iPr₂AMD), or Sc(iPrCp)₂(iPr₂AMD), or any combination thereof.

In particular examples, the method may include wherein the metal comprises lutetium (Lu) and wherein the metal-containing precursor comprises LuCp₃, Lu(MeCp)₃, Lu(EtCp)₃, Lu(iPrCp)₃, Lu(acac)₃, Lu(thd)₃, Lu(OiPr)₃, Lu(OtBu)₃, Lu(N(SiMe₃)₂)₃, Lu(Et₂FMD)₃, Lu(iPr₂FMD)₃, Lu(tBu₂FMD)₃, Lu(iPr₂AMD)₃, Lu(tBu₂AMD)₃, LuCp₂(iPr₂FMD), Lu(MeCp)₂(iPr₂FMD), Lu(EtCp)₂(iPr₂FMD), Lu(iPrCp)₂(iPr₂FMD), LuCp₂(iPr₂AMD), Lu(MeCp)₂(iPr₂AMD), Lu(EtCp)₂(iPr₂AMD), or Lu(iPrCp)₂(iPr₂AMD), or any combination thereof.

In certain examples, the method may include wherein the metal comprises magnesium (Mg) and wherein the metal-containing precursor comprises Mg(acac)₂, Mg(hfac)₂, Mg(thd)₂, MgCp₂, Mg(MeCp)₂, Mg(EtCp)₂, Mg(iPr₂AMD)₂, Mg(sBu₂AMD)₂, Mg(tBu₂AMD)₂, Mg(iPr₂DAD)₂, Mg(tBu₂DAD)₂, or Mg(sBu₂DAD)₂, or any combination thereof.

In various examples, the method may include wherein the metal comprises lanthanum (La) and wherein the metal-containing precursor comprises LaCp₃, La(MeCp)₃, La(EtCp)₃, La(iPrCp)₃, La(tBuCp)₃, La(TMSCp)₃, La(thd)₃, La(N(SiMe₃)₂)₃, La(iPr₂FMD)₃, La(tBu₂FMD)₃, La(sBu₂FMD)₃, La(tPn₂FMD)₃, La(iPr₂AMD)₃, La(tBu₂AMD)₃, La(sBu₂AMD)₃, La(tPn₂AMD)₃, LaCp₂(iPr₂AMD), LaCp₂(tBu₂AMD), LaCp₂(iPr₂FMD), LaCp₂(tBu₂FMD), La(MeCp)₂(iPr₂AMD), La(MeCp)₂(tBu₂AMD), La(MeCp)₂(iPr₂FMD), La(MeCp)₂(tBu₂FMD), La(EtCp)₂(iPr₂AMD), La(EtCp)₂(tBu₂AMD), La(EtCp)₂(iPr₂FMD), La(EtCp)₂(tBu₂FMD), La(iPrCp)₂(iPr₂AMD), La(iPrCp)₂(tBu₂AMD), La(iPrCp)₂(iPr₂FMD), La(iPrCp)₂(tBu₂FMD), La(tBuCp)₂(iPr₂AMD), La(tBuCp)₂(tBu₂AMD), La(tBuCp)₂(iPr₂FMD), or La(tBuCp)₂(tBu₂FMD), or any combination thereof.

In certain examples, the method may include wherein the metal-containing precursor comprises at least one of the following KCp₃, K(MeCp)₃, K(EtCp)₃, K(iPrCp)₃, K(tBuCp)₃, K(TMSCp)₃, K(thd)₃, K(N(SiMe₃)₂)₃, K(iPr₂FMD)₃, K(tBu₂FMD)₃, K(sBu₂FMD)₃, K(tPn₂FMD)₃, K(iPr₂AMD)₃, K(tBu₂AMD)₃, K(sBu₂AMD)₃, K(tPn₂AMD)₃, KCp₂(iPr₂AMD), KCp₂(tBu₂AMD), KCp₂(iPr₂FMD), KCp₂(tBu₂FMD), K(MeCp)₂(iPr₂AMD), K(MeCp)₂(tBu₂AMD), K(MeCp)₂(iPr₂FMD), K(MeCp)₂(tBu₂FMD), K(EtCp)₂(iPr₂AMD), K(EtCp)₂(tBu₂AMD), K(EtCp)₂(iPr₂FMD), K(EtCp)₂(tBu₂FMD), K(iPrCp)₂(iPr₂AMD), K(iPrCp)₂(tBu₂AMD), K(iPrCp)₂(iPr₂FMD), K(iPrCp)₂(tBu₂FMD), K(tBuCp)₂(iPr₂AMD), K(tBuCp)₂(tBu₂AMD), K(tBuCp)₂(iPr₂FMD), or K(tBuCp)₂(tBu₂FMD), or any combination thereof, wherein K is the metal selected from the group comprising cerium (Ce), praseodymium (Pr), neodymium (Nd), samarium (Sm), europium (Eu), gadolinium (Gd), terbium (Tb), dysprosium (Dy) or lanthanum (La).

In some embodiments, the method may include wherein the metal comprises yttrium (Y) and wherein the metal precursor comprises YCp₃, Y(MeCp)₃, Y(EtCp)₃, Y(iPrCp)₃, Y(tBuCp)₃, Y(thd)₃, Y(N(SiMe₃)₂)₃, Y(tBu₂FMD)₃, Y(tBu₂AMD)₃, Y(iPr₂FMD)₃, Y(iPr₂AMD)₃, YCp₂(iPr₂AMD), YCp₂(tBu₂AMD), YCp₂(iPr₂FMD), YCp₂(tBu₂FMD), Y(MeCp)₂(iPr₂AMD), Y(MeCp)₂(tBu₂AMD), Y(MeCp)₂(iPr₂FMD), Y(MeCp)₂(tBu₂FMD), Y(EtCp)₂(iPr₂AMD), Y(EtCp)₂(tBu₂AMD), Y(EtCp)₂(iPr₂FMD), Y(EtCp)₂(tBu₂FMD), Y(iPrCp)₂(iPr₂AMD), Y(iPrCp)₂(tBu₂AMD), Y(iPrCp)₂(iPr₂FMD), or Y(iPrCp)₂(tBu₂FMD), or any combination thereof.

In particular examples, the method may include wherein the metal-containing precursor comprises at least one of the following JCp₃, J(MeCp)₃, J(EtCp)₃, J(iPrCp)₃, J(tBuCp)₃, J(thd)₃, J(N(SiMe₃)₂)₃, J(tBu₂FMD)₃, J(tBu₂AMD)₃, J(iPr₂FMD)₃, J(iPr₂AMD)₃, JCp₂(iPr₂AMD), JCp₂(tBu₂AMD), JCp₂(iPr₂FMD), JCp₂(tBu₂FMD), J(MeCp)₂(iPr₂AMD), J(MeCp)₂(tBu₂AMD), J(MeCp)₂(iPr₂FMD), J(MeCp)₂(tBu₂FMD), J(EtCp)₂(iPr₂AMD), J(EtCp)₂(tBu₂AMD), J(EtCp)₂(iPr₂FMD), J(EtCp)₂(tBu₂FMD), J(iPrCp)₂(iPr₂AMD), J(iPrCp)₂(tBu₂AMD), J(iPrCp)₂(iPr₂FMD), or J(iPrCp)₂(tBu₂FMD), or any combination thereof, where J is the metal selected from the group comprising holmium (Ho), erbium (Er), thulium (Tm), ytterbium (Yb) or yttrium (Y).

For the purpose of summarizing the disclosure and the advantages achieved over the prior art, certain objects and advantages of the disclosure have been described herein above. Of course, it should be understood that not necessarily all such objects or advantages can be achieved in accordance with any particular embodiment or example of the disclosure. Thus, for example, those skilled in the art will recognize that the examples disclosed herein can be carried out in a manner that achieves or optimizes one advantage or group of advantages as taught or suggested herein without necessarily achieving other objects or advantages as can be taught or suggested herein. All of these examples are intended to be within the scope of the disclosure. These and other embodiments will become readily apparent to those skilled in the art from the following detailed description of certain examples having reference to the attached figures, the disclosure not being limited to any particular example(s) discussed.

### BRIEF DESCRIPTION OF THE DRAWING FIGURES

A more complete understanding of the embodiments of the present disclosure may be derived by referring to the detailed description and claims when considered in connection with the following illustrative figures.

FIG. 1 illustrates a method in accordance with exemplary embodiments of the disclosure.

FIGS. 2A-2C illustrate exemplary structures in accordance with embodiments of the disclosure.

FIG. 3 illustrates an exemplary structure in accordance with embodiments of the disclosure.

FIG. 4 illustrates an exemplary structure in accordance with embodiments of the disclosure.

FIG. 5 illustrates a reactor system in accordance with additional exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The detailed description of various examples herein makes reference to the accompanying drawings, which show the exemplary examples by way of illustration. While these exemplary examples are described in sufficient detail to enable those skilled in the art to practice the disclosure, it should be understood that other examples may be realized and that logical, chemical, and/or mechanical changes may be made without departing from the spirit and scope of the disclosure. Thus, the detailed description herein is presented for purposes of illustration only and not of limitation. For example, the steps recited in any of the method or process descriptions can be executed in any combination and/or order and are not limited to the combination and/or order presented. Further, one or more steps from one of the disclosed methods or processes can be combined with one or more steps from another of the disclosed methods or processes in any suitable combination and/or order. Moreover, any of the functions or steps can be outsourced to or performed by one or more third parties. Furthermore, any reference to singular includes plural examples, and any reference to more than one component can include a singular example.

Although certain embodiments and examples are disclosed below, it will be understood by those in the art that the disclosure extends beyond the specifically disclosed examples and/or uses of the disclosure and obvious modifications and equivalents thereof. Thus, it is intended that the scope of the disclosure should not be limited by the particular examples described herein.

The illustrations presented herein are not meant to be actual views of any particular material, apparatus, structure, or device, but are merely representations that are used to describe examples of the disclosure.

As used herein, the term “atomic layer deposition” (ALD) can refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) can subsequently be introduced into the process chamber for use in converting the chemisorbed precursor to the desired material on the deposition surface. Typically, this reactant is capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) can refer to any process wherein a substrate is exposed to one or more volatile precursors, which react and/or decompose on a substrate surface to produce a desired deposition.

Further, in this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, or the like. Further, in this disclosure, the terms “including,” “constituted by” and “having” can refer independently to “typically or broadly comprising,” “comprising,” “consisting essentially of,” or “consisting of” in some examples. In this disclosure, any defined meanings do not necessarily exclude ordinary and customary meanings in some examples.

As transistor scaling in logic devices move forward, there will be less available space to increase the density of transistors and lower the power consumption. Interface dipole engineering has drawn increasing attention to address the scaling challenges due to its advantages as a volume-less effective work function (eWF) and threshold voltage (Vt) tuning technique. Threshold voltage shifting layers can enhance semiconductor device performance by modulating the effective work function (EWF) of a metal-oxide-semiconductor (MOS) device. In some embodiments, a threshold voltage shifting layer can be formed, e.g., by a deposition process, over, or directly over the gate dielectric of a metal-oxide-semiconductor (MOS) device, and the properties of the threshold voltage shifting layer (including, but not limited to, material composition, thickness, and deposition method) can alter the band alignment in the MOS device to provide a device with a preferred operating performance.

In some embodiments, threshold shifting layers comprise oxygen and may generate SiOx at the interface, which can increase the equivalent oxide thickness (EOT) of the device. Therefore, a threshold voltage shifting layer which is fabricated with lower-oxygen-content materials or oxygen-free materials and is substantially free of oxygen or has a reduced oxygen composition as a way to control the effective oxide thickness to improve the electrical performance of the end device may be desirable.

A dipole first (DF) scheme, wherein the threshold voltage shifting layer is deposited on, for example, an SiO₂ interface layer (IL) before the deposition of a high-k dielectric, may enable the thermal budget reduction of gate stack processes and provide a larger shift compared to a dipole last (DL) scheme, wherein the threshold voltage shifting layer is deposited on high-k. This could, however, deteriorate the interface quality of IL (e.g., IL regrowth may occur during the drive-in anneal) and lead to an increase of effective oxide thickness (EOT) penalty.

The present disclosure includes methods, systems and devices for forming a semiconductor structure including a threshold voltage shifting layer. This disclosure describes alternative n-dipole candidates that may possess a reduced EOT penalty even in a dipole first scheme and which are more integration-friendly for future logic structures such as gate-all-around (GAA) transistors and complementary field effect transistors (CFET). Metal-containing candidates (e.g., containing candidates including cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), titanium (Ti), zirconium (Zr), hafnium (Hf), tantalum (Ta), scandium (Sc), lutetium (Lu), yttrium (Y), magnesium (Mg), lanthanum (La), or strontium (Sr), or a combination thereof) that have less oxygen content or that are oxygen-free or substantially oxygen-free (e.g., scandium nitride (ScNx), scandium oxynitride (ScOxNy), scandium carbide (ScCx), scandium oxycarbide (ScOxCy), lanthanum nitride (LaNx), lanthanum oxynitride (LaOxNy), lanthanum carbide (LaCx), or scandium oxycarbide (LaOxCy) or a combination thereof) may provide finer tunability and reduced EOT penalty compared to n-dipole candidates having a greater oxygen content or composition. This could help to prevent or reduce the extent of IL regrowth since the amount of oxygen around the IL interface may be more sensitive when the threshold voltage shifting layer is directly deposited on top.

Exemplary methods can be used to, for example, form gate electrodes, and/or form metal layers suitable for metal oxides semiconductor (MOS) applications (e.g., as a work function layer and/or threshold voltage shifting layer, dipole or flatband shifter), such as in the formation of complimentary MOS (CMOS) devices, for use as etch stop layers, and/or for use as barrier or liner layers (e.g., in FEOL, MEOL and BEOL processing). For example, the metal threshold voltage shifting layers can be used in the formation of logic devices, dynamic random-access memory (DRAM), three-dimensional NAND devices, as a metal layer gate of a logic device, as a n-dipole layer for logic devices, and the like. Such n-dipole candidates may reduce EOT penalty and may be more integration-friendly for future logic structures such as gate-all-around (GAA) transistors and complementary field effect transistors (CFET). However, unless noted otherwise, the invention is not necessarily limited to such examples.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include helium, argon, and any combination thereof. In some cases, an inert gas can include nitrogen and/or hydrogen.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material and an insulating or dielectric material layer overlying at least a portion of the bulk semiconductor material.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

As used herein, a “structure” can be or include a substrate as described herein. Structures can include one or more layers overlying the substrate, such as one or more layers formed according to a method as described herein. Device portions can be or include structures.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

As used herein “oxygen-free” or “substantially oxygen-free” can refer to a material such as a metal layer that is oxygen-free or substantially oxygen-free comprising less than about 7% oxygen, or less than about 5% oxygen, or less than about 4% oxygen, or less than about 3% oxygen, or less than about 2% oxygen, or less than about 1% oxygen, or less than about 0.1% oxygen, (“about” in this context means plus or minus 0.05%).

In certain examples, a metal component of the threshold voltage shifting layer may comprise, cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), titanium (Ti), zirconium (Zr), hafnium (Hf), tantalum (Ta), scandium (Sc), lutetium (Lu), yttrium (Y), magnesium (Mg), lanthanum (La), or strontium (Sr), or a combination thereof

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

This disclosure may use the following abbreviations: Me may refer to methyl, Et may refer to ethyl, iPr may refer to isopropyl, tBu may refer to tert-butyl, iBu may refer to isobutyl, Np may refer to neopentyl, Cp may refer to cyclopentadienyl, MeCp may refer to methylcyclopentadienyl, EtCp may refer to ethylcyclopentadienyl, iPrCp may refer to isopropylcyclopentadienyl, nPrCp may refer to n-propyl cyclopentadienyl, tBuCp may refer to tert-butyl cyclopentadienyl, TMSCp may refer to trimethylsilylcyclopentadienyl, nPr may refer to n-propyl, nBu may refer to n-butyl, acac may refer to acetylacetonate, hfac may refer to hexafluoroacetylacetonate, OMe may refer to methoxide, OEt may refer to ethoxide, OiPr may refer to isopropoxide, OtBu may refer to tert-butoxide, mmp may refer to 1-methoxy-2-methyl-2-propoxide, dmap may refer to 1-dimethylamino-2-propoxide, dmamp may refer to 1-dimethylamino-2-methyl-2-propoxide, dmamb may refer to 1-dimethylamino-2-methyl-2-butoxide, acac may refer to acetylacetonate, hfac may refer to 1,1,1,5,5,5-hexafluoropentane-2,5-dionate, thd may refer to 2,2,6,6-tetramethylheptane-3,5-dionate, phen may refer to phenanthroline, tBu2DAD may refer to 1,4-di-tert-butyl-1,4-diaza-1,3-butadiene, iPr₂DAD may refer to 1,4-diisopropyl-1,4-diaza-1,3-butadiene, sBu₂DAD may refer to 1,4-di-sec-butyl-1,4-diaza-1,3-butadiene and tPn₂DAD may refer to 1,4-di-tert-pentyl-1,4-diaza-1,3-butadiene.

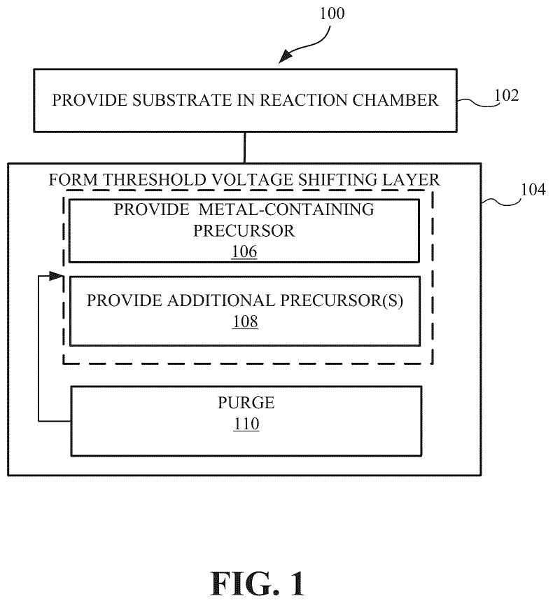

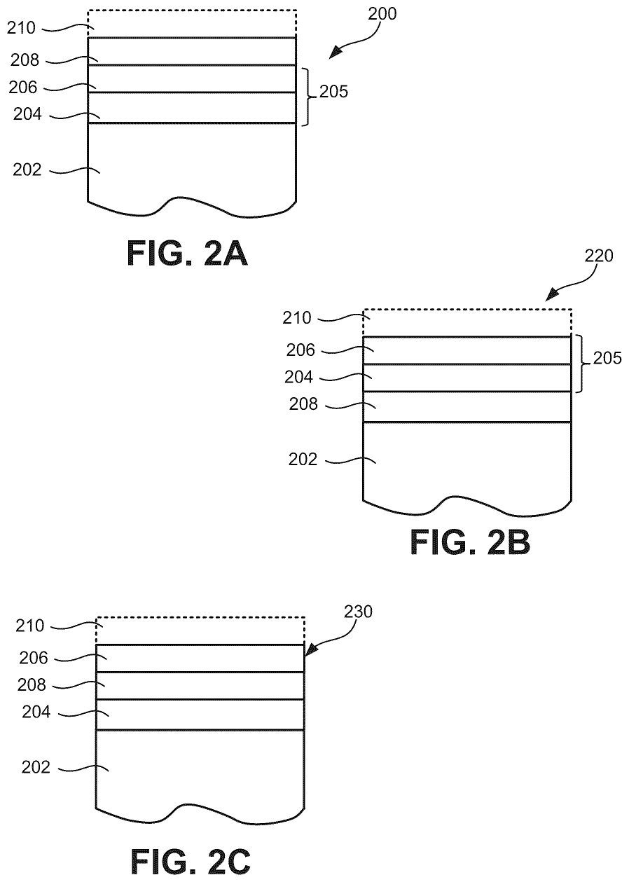

FIG. 1 illustrates an example process 100 in accordance with exemplary embodiments of the disclosure. Process 100 will be described with reference to FIGS. 1-2C.

In an example, process 100 can be used to, for example, form a structure including a threshold voltage shifting layer (e.g., threshold voltage shifting layer 208 illustrated in FIGS. 2A-2C) which may comprise a metal having the formula M(NxCyOz), wherein M is a metal, N is nitrogen, C is carbon, and O is oxygen, wherein x=0 to 5, y=0 to 5, z=0 to (x+y), and wherein (x+y)≥0.1. In some embodiments, (x+y)≥1.0. Thus, in an example, threshold voltage shifting layer 208 may comprise a reduced amount of oxygen, may be oxygen-free or may be substantially oxygen-free. The threshold voltage shifting layer can be used during formation of a device, such as a device noted herein. However, unless otherwise noted, methods are not limited to such applications.

Process 100 includes the steps of providing a substrate within a reaction chamber of a reactor (step 102) and using a cyclical deposition process, depositing a layer comprising a threshold voltage shifting layer onto a surface of the substrate (step 104).

During step 102, a substrate is provided within a reaction chamber. The reaction chamber used during step 102 can be or include a reaction chamber of a chemical vapor deposition reactor system configured to perform a cyclical deposition process. The reaction chamber can be a standalone reaction chamber or part of a cluster tool.

Step 102 can include heating the substrate to a desired deposition temperature within the reaction chamber. In some embodiments of the disclosure, step 102 includes heating the substrate to a temperature of less than 800° C. For example, in some embodiments of the disclosure, heating the substrate to a deposition temperature may comprise heating the substrate to a temperature between approximately 20° C. and approximately 800° C., about 100° C. and about 400° C., about 20° C. and about 300° C., or about 20° C. and about 200° C.

In addition to controlling the temperature of the substrate, a pressure within the reaction chamber may also be regulated. For example, in some embodiments of the disclosure, the pressure within the reaction chamber during step 102 may be less than 760 Torr or between about 0.1 Torr and 760 Torr, or between about 1 Torr and 100 Torr, or between about 1 Torr and 10 Torr.

During step 104, a threshold voltage shifting layer is deposited onto a surface of the substrate using a cyclical deposition process. As noted above, the cyclical deposition process can include cyclical CVD, ALD, or a hybrid cyclical CVD/ALD process. For example, in some embodiments, the growth rate of a particular ALD process may be low compared with a CVD process. One approach to increase the growth rate may be that of operating at a higher deposition temperature than that typically employed in an ALD process, resulting in some portion of a chemical vapor deposition process, but still taking advantage of the sequential introduction of reactants. Such a process may be referred to as cyclical CVD. In some embodiments, a cyclical CVD process may comprise the introduction of two or more reactants into the reaction chamber, wherein there may be a time period of overlap between the two or more reactants in the reaction chamber resulting in both an ALD component of the deposition and a CVD component of the deposition. This is referred to as a hybrid process.

In accordance with further examples, a cyclical deposition process may comprise pulsing and/or flowing of a metal-containing precursor (step 106) and/or pulsing and/or flowing of additional precursor (step 108) into the reaction chamber. Such pulsing and/or flowing of the metal-containing precursor (step 106) and/or the additional precursor (step 108) may be sequential, concurrent, cyclic, and/or repeating, and claimed subject matter is not limited in this regard. In certain examples, the metal-containing precursor may be an oxygen-free or substantially oxygen-free metal-containing precursor. Likewise, the additional precursor may be an oxygen-free or a substantially oxygen-free additional precursor.

By way of particular examples, the metal in the metal-containing precursor may comprise cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), titanium (Ti), zirconium (Zr), hafnium (Hf), tantalum (Ta), scandium (Sc), lutetium (Lu), yttrium (Y), magnesium (Mg), lanthanum (La), or strontium (Sr), or a combination thereof. The additional precursor may comprise at least one of nitrogen (N) or carbon (C). In some embodiments, the additional precursor may be oxygen-free or substantially oxygen-free. In some examples, the additional precursor may comprise oxygen (O).

In some examples, the metal-containing precursor may comprise a cyclopentadienyl ligand. In some examples, such a cyclopentadienyl ligand may comprise at least one of cyclopentadienyl (Cp), methylcyclopentadienyl (MeCp), ethylcyclopentadienyl (EtCp), isopropylcyclopentadienyl (iPrCp), tert-butylcyclopentadienyl (tBuCp), trimethylsilylcyclopentadienyl (TMSCp), pentamethylcyclopentadientyl (Cp*), 1,2,4-triisopropylcyclopentadienyl (iPr₃Cp), and 1,2,4-tri-tert-butylcyclopentadienyl (tBu₃Cp).

In various examples, the metal-containing precursor may comprise an amido ligand. In some examples, such an amido ligand may comprise at least one of dimethylamido (NMe₂), diethylamido (NEt₂), ethylmethylamido (NEtMe), diisopropylamido (NiPr₂), tert-butylamino (NHtBu), and bis(trimethylsilyl)amido (N(SiMe₃)₂).

In some examples, the metal-containing precursor may comprise an imido ligand. In certain examples, such an imido ligand may comprise at least one of ethylimido (NEt), isoproptylimido (NiPr), isobutylimido (NiBu), tert-butylimido (NtBu), and tert-pentylimido (NtPn).

In other particular examples, the metal-containing precursor may comprise an amidinate ligand. In some examples, such an amidinate ligand may comprise at least one of N,N′-diethylacetamidinate (Et₂AMD), N,N′-diisopropylacetamidinate (iPr₂AMD), N,N′-diisopropylformamidinate (iPr₂FMD), N,N′-di-tert-butylacetamidinate (tBu₂AMD), and N,N′-di-tert-butylformamidinate (tBu₂FMD).

In particular examples, the metal-containing precursor may comprise a halogen ligand. In some examples, such a halogen ligand may comprise, at least one of (F) fluorine, (Cl) chlorine, (Br) bromine or (I) iodine.

In some examples, the metal-containing precursor may comprise an alkyl ligand. In certain examples, such an alkyl ligand may comprise, at least one of methyl (Me), ethyl (Et), isopropyl (iPr), tert-butyl (tBu), isobutyl (iBu), and neopentyl (Np).

In various embodiments, the metal-containing precursor may comprise an alkoxide ligand. In some examples, such an alkoxide ligand may comprise, at least one of methoxide (OMe), ethoxide (OEt), isopropoxide (OiPr), tert-butoxide (OtBu), 1-methoxy-2-methyl-2-propoxide (mmp), 1-dimethylamino-2-propoxide (dmap), 1-dimethylamino-2-methyl-2-propoxide (dmamp), and 1-dimethylamino-2-methyl-2-butoxide (dmamb).

In certain embodiments, the metal-containing precursor may comprise a diketonate ligand. In some examples, such a diketonate ligand may comprise, at least one of acetylacetonate (acac), 2,2,6,6-tetramethylheptane-3,5-dionate (thd), and 1,1,1,5,5,5-hexafluoropentane-2,5-dionate (hfac).

In some examples, the metal-containing precursor may comprise a diazabutadiene ligand. In some examples, such a diazabutadiene ligand may comprise, at least one of 1,4-di-tert-butyl-1,4-diaza-1,3-butadiene (tBu₂DAD), 1,4-diisopropyl-1,4-diaza-1,3-butadiene (iPr₂DAD), 1,4-di-sec-butyl-1,4-diaza-1,3-butadiene (sBu₂DAD) and 1,4-di-tert-pentyl-1,4-diaza-1,3-butadiene (tPn₂DAD).

In certain examples, one of the one or more additional precursors may be a nitrogen-containing precursor. In some examples, the nitrogen-containing precursor may be selected from: ammonia, hydrazine, tert-butylhydrazine, dimethylhydrazine, methylhydrazine, phenylhydrazine, tert-butylamine, isobutylamine, tert-pentylamine, N₂ plasma, NH₃ plasma, or N₂/H₂ plasma, or any combination thereof.

In some embodiments, one of the one or more additional precursors may be a carbon-containing precursor. In some examples, the carbon-containing precursor may be selected from: iodomethane, diiodomethane, iodoethane, 1,2-diiodoethane, bromoethane, 1,2-dibromoethane, bromobenzene, iodobenzene, 1-iodobutane, dicyclopentadiene, acetylene, propargyl bromide, allyl bromide, or allyl iodide, or a combination thereof.

In some examples, one of the one or more additional precursors is an oxygen-containing precursor. In some examples, the oxygen-containing precursor may be selected from: H₂O, ozone, N₂O, H₂O₂, O₂, or O₂ plasma, or any combination thereof.

In particular examples, the metal may comprise titanium (Ti) and the metal-containing precursor may comprise TiF₄, TiCl₄, TiBr₄, TiI₄, Ti(NMe₂)₄, Ti(NEtMe)₄, Ti(NEt₂)₄, Ti(OMe)₄, Ti(OEt)₄, Ti(OiPr)₄, Ti(OtBu)₄, Ti(MeCp)(OiPr)₃, TiCp*(OMe)₃, TiCp(NMe₂)₄, Ti(EtCp)(NMe₂)₄, Ti(OiPr)₂(NMe₂)₂, Ti(OiPr)₂(thd)₂, Ti(OiPr)₃(iPr₂AMD), or Ti(Np)₄, or a combination thereof.

In certain examples, the metal may comprise zirconium (Zr) and the metal-containing precursor may comprise ZrCl₄, ZrI₄, Zr(NMe₂)₄, Zr(NEtMe)₄, Zr(NEt₂)₄, Zr(thd)₄, Zr(OiPr)₄, Zr(OtBu)₄, ZrCp(NMe₂)₃, Zr(MeCp)(NMe₂)₃, Zr(EtCp)(NMe₂)₃, ZrCp(NEt₂)₃, Zr(MeCp)(NEt₂)₃, Zr(EtCp)(NEt₂)₃, ZrCp(NEtMe)₃, Zr(MeCp)(NEtMe)₃, Zr(EtCp)(NEtMe)₃, ZrCp₂Cl₂, ZrCp₂Me₂, ZrCp₂(OMe)₂, ZrCp₂Me(OMe), ZrCp₂(NMe₂)₂, Zr(MeCp)₂Cl₂, Zr(MeCp)₂Me₂, Zr(MeCp)₂(OMe)₂, Zr(MeCp)₂Me(OMe), Zr(MeCp)₂(NMe₂)₂, Zr(EtCp)₂Cl₂, Zr(EtCp)₂Me₂, Zr(EtCp)₂(OMe)₂, Zr(EtCp)₂Me(OMe), Zr(EtCp)₂(NMe₂)₂, ZrNp₄, or ZrCp(tBu₂DAD)(OiPr), or any combination thereof.

In various examples, the metal may comprise hafnium (Hf) and the metal-containing precursor may comprise HfCl₄, HfI₄, Hf(NMe₂)₄, Hf(NEtMe)₄, Hf(NEt₂)₄, Hf(thd)₄, Hf(OiPr)₄, Hf(OtBu)₄, Hf(BH₄)₄, HfCp(NMe₂)₃, Hf(MeCp)(NMe₂)₃, Hf(EtCp)(NMe₂)₃, HfCp(NEt₂)₃, Hf(MeCp)(NEt₂)₃, Hf(EtCp)(NEt₂)₃, HfCp(NEtMe)₃, Hf(MeCp)(NEtMe)₃, Hf(EtCp)(NEtMe)₃, HfCp₂Cl₂, HfCp₂Me₂, HfCp₂(OMe)₂, HfCp₂Me(OMe), HfCp₂(NMe₂)₂, Hf(MeCp)₂Cl₂, Hf(MeCp)₂Me₂, Hf(MeCp)₂(OMe)₂, Hf(MeCp)₂Me(OMe), Hf(MeCp)₂(NMe₂)₂, Hf(EtCp)₂Cl₂, Hf(EtCp)₂Me₂, Hf(EtCp)₂(OMe)₂, Hf(EtCp)₂Me(OMe), Hf(EtCp)₂(NMe₂)₂, Hf(MeCp)₂(mmp)Me, Hf(OtBu)₂(mmp)₂, Hf(iPr₂FMD)₂(NMe₂)₂, HfNp₄, Hf(dmap)₄, or Hf(mmp)₄, or any combination thereof.

In particular examples, the metal may comprise tantalum (Ta) and the metal-containing precursor may comprise TaF₅, TaCl₅, TaBr₅, TaI₅, Ta(NMe₂)₅, Ta(NEt₂)₅, Ta(NEtMe)₅, Ta(NtBu)(NMe₂)₃, Ta(NtBu)(NEt₂)₃, Ta(NtBu)(NEtMe)₃, Ta(NiPr)(NEtMe)₃, Ta(NtPn)(NMe₂)₃, Ta(OEt)₅, TaNp₃Cl₂, Ta(NtBu) Cl₃, Ta(NtPn) Cl₃, or Ta(NtBu)(iPr₂AMD)₂(NMe₂), or any combination thereof.

In various examples, the metal may comprise scandium (Sc) and the metal-containing precursor may comprise ScCp₃, Sc(MeCp)₃, Sc(EtCp)₃, Sc(iPrCp)₃, Sc(acac)₃, Sc(thd)₃, Sc(N(SiMe₃)₂)₃, Sc(Et₂AMD)₃, Sc(iPr₂FMD)₃, Sc(iPr₂AMD)₃, Sc(tBu₂FMD)₃, Sc(tBu₂AMD)₃, ScCp₂(iPr₂FMD), Sc(MeCp)₂(iPr₂FMD), Sc(EtCp)₂(iPr₂FMD), Sc(iPrCp)₂(iPr₂FMD), ScCp₂(iPr₂AMD), Sc(MeCp)₂(iPr₂AMD), Sc(EtCp)₂(iPr₂AMD), or Sc(iPrCp)₂(iPr₂AMD), or any combination thereof.

In certain examples, the metal may comprise lutetium (Lu) and the metal-containing precursor may comprise LuCp₃, Lu(MeCp)₃, Lu(EtCp)₃, Lu(iPrCp)₃, Lu(acac)₃, Lu(thd)₃, Lu(OiPr)₃, Lu(OtBu)₃, Lu(N(SiMe₃)₂)₃, Lu(Et₂FMD)₃, Lu(iPr₂FMD)₃, Lu(tBu₂FMD)₃, Lu(iPr₂AMD)₃, Lu(tBu₂AMD)₃, LuCp₂(iPr₂FMD), Lu(MeCp)₂(iPr₂FMD), Lu(EtCp)₂(iPr₂FMD), Lu(iPrCp)₂(iPr₂FMD), LuCp₂(iPr₂AMD), Lu(MeCp)₂(iPr₂AMD), Lu(EtCp)₂(iPr₂AMD), or Lu(iPrCp)₂(iPr₂AMD), or any combination thereof.

In various examples, the metal may comprise magnesium (Mg) and the metal-containing precursor may comprise Mg(acac)₂, Mg(hfac)₂, Mg(thd)₂, MgCp₂, Mg(MeCp)₂, Mg(EtCp)₂, Mg(iPr₂AMD)₂, Mg(sBu₂AMD)₂, Mg(tBu₂AMD)₂, Mg(iPr₂DAD)₂, Mg(tBu₂DAD)₂, or Mg(sBu₂DAD)₂, or any combination thereof.

In particular examples, the metal may comprise lanthanum (La) and the metal-containing precursor may comprise LaCp₃, La(MeCp)₃, La(EtCp)₃, La(iPrCp)₃, La(tBuCp)₃, La(TMSCp)₃, La(thd)₃, La(N(SiMe₃)₂)₃, La(iPr₂FMD)₃, La(tBu₂FMD)₃, La(sBu₂FMD)₃, La(tPn₂FMD)₃, La(iPr₂AMD)₃, La(tBu₂AMD)₃, La(sBu₂AMD)₃, La(tPn₂AMD)₃, LaCp₂(iPr₂AMD), LaCp₂(tBu₂AMD), LaCp₂(iPr₂FMD), LaCp₂(tBu₂FMD), La(MeCp)₂(iPr₂AMD), La(MeCp)₂(tBu₂AMD), La(MeCp)₂(iPr₂FMD), La(MeCp)₂(tBu₂FMD), La(EtCp)₂(iPr₂AMD), La(EtCp)₂(tBu₂AMD), La(EtCp)₂(iPr₂FMD), La(EtCp)₂(tBu₂FMD), La(iPrCp)₂(iPr₂AMD), La(iPrCp)₂(tBu₂AMD), La(iPrCp)₂(iPr₂FMD), La(iPrCp)₂(tBu₂FMD), La(tBuCp)₂(iPr₂AMD), La(tBuCp)₂(tBu₂AMD), La(tBuCp)₂(iPr₂FMD), or La(tBuCp)₂(tBu₂FMD), or any combination thereof.

In certain examples, the metal-containing precursor may comprise KCp₃, K(MeCp)₃, K(EtCp)₃, K(iPrCp)₃, K(tBuCp)₃, K(TMSCp)₃, K(thd)₃, K(N(SiMe₃)₂)₃, K(iPr₂FMD)₃, K(tBu₂FMD)₃, K(sBu₂FMD)₃, K(tPn₂FMD)₃, K(iPr₂AMD)₃, K(tBu₂AMD)₃, K(sBu₂AMD)₃, K(tPn₂AMD)₃, KCp₂(iPr₂AMD), KCp₂(tBu₂AMD), KCp₂(iPr₂FMD), KCp₂(tBu₂FMD), K(MeCp)₂(iPr₂AMD), K(MeCp)₂(tBu₂AMD), K(MeCp)₂(iPr₂FMD), K(MeCp)₂(tBu₂FMD), K(EtCp)₂(iPr₂AMD), K(EtCp)₂(tBu₂AMD), K(EtCp)₂(iPr₂FMD), K(EtCp)₂(tBu₂FMD), K(iPrCp)₂(iPr₂AMD), K(iPrCp)₂(tBu₂AMD), K(iPrCp)₂(iPr₂FMD), K(iPrCp)₂(tBu₂FMD), K(tBuCp)₂(iPr₂AMD), K(tBuCp)₂(tBu₂AMD), K(tBuCp)₂(iPr₂FMD), or K(tBuCp)₂(tBu₂FMD), or any combination thereof, where K may be the metal selected from the group comprising cerium (Ce), praseodymium (Pr), neodymium (Nd), samarium (Sm), europium (Eu), gadolinium (Gd), terbium (Tb), dysprosium (Dy) or lanthanum (La).

In certain examples, the metal may comprise yttrium (Y) and the metal-containing precursor may comprise YCp₃, Y(MeCp)₃, Y(EtCp)₃, Y(iPrCp)₃, Y(tBuCp)₃, Y(thd)₃, Y(N(SiMe₃)₂)₃, Y(tBu₂FMD)₃, Y(tBu₂AMD)₃, Y(iPr₂FMD)₃, Y(iPr₂AMD)₃, YCp₂(iPr₂AMD), YCp₂(tBu₂AMD), YCp₂(iPr₂FMD), YCp₂(tBu₂FMD), Y(MeCp)₂(iPr₂AMD), Y(MeCp)₂(tBu₂AMD), Y(MeCp)₂(iPr₂FMD), Y(MeCp)₂(tBu₂FMD), Y(EtCp)₂(iPr₂AMD), Y(EtCp)₂(tBu₂AMD), Y(EtCp)₂(iPr₂FMD), Y(EtCp)₂(tBu₂FMD), Y(iPrCp)₂(iPr₂AMD), Y(iPrCp)₂(tBu₂AMD), Y(iPrCp)₂(iPr₂FMD), or Y(iPrCp)₂(tBu₂FMD), or any combination thereof.

In particular examples, the metal-containing precursor may comprise JCp₃, J(MeCp)₃, J(EtCp)₃, J(iPrCp)₃, J(tBuCp)₃, J(thd)₃, J(N(SiMe₃)₂)₃, J(tBu₂FMD)₃, J(tBu₂AMD)₃, J(iPr₂FMD)₃, J(iPr₂AMD)₃, JCp₂(iPr₂AMD), JCp₂(tBu₂AMD), JCp₂(iPr₂FMD), JCp₂(tBu₂FMD), J(MeCp)₂(iPr₂AMD), J(MeCp)₂(tBu₂AMD), J(MeCp)₂(iPr₂FMD), J(MeCp)₂(tBu₂FMD), J(EtCp)₂(iPr₂AMD), J(EtCp)₂(tBu₂AMD), J(EtCp)₂(iPr₂FMD), J(EtCp)₂(tBu₂FMD), J(iPrCp)₂(iPr₂AMD), J(iPrCp)₂(tBu₂AMD), J(iPrCp)₂(iPr₂FMD), or J(iPrCp)₂(tBu₂FMD), or any combination thereof, where J may be the metal selected from the group comprising holmium (Ho), erbium (Er), thulium (Tm), ytterbium (Yb) or yttrium (Y).

The cyclical deposition process can include (e.g., separately and/or sequentially) providing a metal-containing precursor (step 106) to the reaction chamber and providing at least one additional precursor to the reaction chamber (step 108). A purge may be carried out at any point during the cyclical process, for example, to remove byproducts (step 110). Purge step 110 may be executed before or after providing the metal-containing precursor and each of the one or more additional precursors and/or reactants to the chamber.

In some cases, two or more precursors and/or two or more reactants can be flowed to the reaction chamber, such that the two or more precursors and/or two or more reactants overlap within the reaction chamber. For example, one or more metal-containing precursors and/or one or more additional precursors can be co-flowed to the reaction chamber.

In the case of thermal cyclical deposition processes, a duration of the step of providing the metal-containing precursor and/or the one or more additional precursors to the reaction chamber can be relatively long to allow the reactant to react with the precursor or a derivative thereof. For example, the duration can be greater than or equal to 0.1 seconds or greater than or equal to 60 seconds or between about 0.1 and 60 seconds.

As part of step 104, the reaction chamber can be purged (step 110) using a vacuum and/or an inert gas to, for example, mitigate gas phase reactions between reactants and enable self-saturating surface reactions—e.g., in the case of ALD. Additionally or alternatively, the substrate may be moved to separately contact a first vapor phase reactant and a second vapor phase reactant. Surplus chemicals and reaction byproducts, if any, can be removed from the substrate surface or reaction chamber, such as by purging the reaction space or by moving the substrate, before the substrate is contacted with the next reactive chemical. The reaction chamber can be purged before and/or after providing the metal-containing precursor to the reaction chamber (step 106) and/or before and/or after providing one or more additional precursors to the reaction chamber (step 108).

In some embodiments of the disclosure, process 100 includes repeating a unit deposition cycle that includes (1) providing one or more of a metal-containing precursor to the reaction chamber and (2) providing one or more additional precursors to the reaction chamber, with optional purge or more steps after step (1) and/or step (2). The deposition cycle can be repeated one or more times, based on, for example, desired thickness of the threshold voltage shifting layer. For example, if the thickness of the threshold voltage shifting layer is less than desired for a particular application, then the step of (1) providing a metal-containing precursor to the reaction chamber and (2) providing one or more additional precursor(s) to the reaction chamber can be repeated one or more times. Once the threshold voltage shifting layer has been deposited to a desired thickness, the substrate can be subjected to additional processes to form a device structure and/or device.

In some embodiments, a step coverage of the threshold voltage shifting layer is equal to or greater than about 50%, or greater than about 80%, or greater than about 90%, or about 95%, or about 98%, or about 99% or greater, in/on structures having aspect ratios (height/width) of more than about 2, more than about 5, more than about 10, more than about 25, more than about 50, more than about 100, or between about 10 and 100 or about 5 and about 25.

A growth rate of the threshold voltage shifting layer can be relatively low—e.g., less than 3 angstroms/cycle, between about 0.2 and 3 angstroms/cycle, or about 0.1 to about 1 angstrom/cycle. The relatively low growth rate can facilitate desired accuracy of film thickness and/or film thickness uniformity. In an example, a threshold voltage shifting layer may be operational even if not fully closed as their total thickness may be less than one angstrom. Thus, a low growth rate and high accuracy may be advantageous in the case of such a thin layer.

FIG. 2A illustrates a structure/a portion of a device 200 in accordance with additional examples of the disclosure. Device or structure 200 includes a substrate 202, dielectric or insulating material 205, and a threshold voltage shifting layer 208. In an example and as discussed in greater detail hereinabove, the threshold voltage shifting layer 208 may comprise a metal represented by the formula M(NxCyOz), wherein M is a metal, N is nitrogen, C is carbon, and O is oxygen, wherein x=0 to 5, y=0 to 5, z=0 to (x+y), wherein (x+y)≥0.1. In some examples, (x+y)≥0. In some examples, (x+y)≥1. In some examples, x=0 to 2 and y=0 to 2. In some examples, threshold voltage shifting layer 208 is oxygen-free or substantially oxygen-free. In the illustrated example, structure 200 also includes an additional conducting layer 210. Substrate 202 can be or include any of the substrate materials described herein.

Dielectric or insulating material 205 can include one or more dielectric or insulating material layers. By way of example, dielectric or insulating material 205 can include an interface layer 204 and a high-k material 206 deposited overlying interface layer 204. Threshold voltage shifting layer 208 is deposited in a dipole last pattern directly onto the high-k material 206 surface.

In some cases, interface layer 204 may not exist or may not exist to an appreciable extent. Interface layer 204 can include an oxide, such as a silicon oxide, which can be formed on a surface of the substrate 202 using, for example, a chemical oxidation process or an oxide deposition process. High-k material 206 can be or include, for example, a metallic oxide having a dielectric constant greater than about 7. In some embodiments, the high-k material has a dielectric constant higher than the dielectric constant of silicon oxide. Exemplary high-k materials include one or more of hafnium oxide (HfO₂), tantalum oxide (Ta₂O₅), zirconium oxide (ZrO₂), titanium oxide (TiO₂), hafnium silicate (HfSiOx), aluminum oxide (Al₂O₃), lanthanum oxide (La₂O₃), and mixtures/laminates comprising one or more such layers.

In an example, threshold voltage shifting layer 208 can be formed according to methods described herein. Because threshold voltage shifting layer 208 is formed using a cyclical deposition process, a concentration of metal, nitrogen, carbon, oxygen and/or other constituents in threshold voltage shifting layer 208 can vary from a bottom of threshold voltage shifting layer 208 to a top of threshold voltage shifting layer 208 by, for example, controlling an amount of metal-containing precursor and/or additional precursor(s) and/or respective pulse times during one or more deposition cycles. In some cases, threshold voltage shifting layer 208 can have a stochiometric composition. In some examples, threshold voltage shifting layer 208 can have a non-stoichiometric composition. A work function and other properties of threshold voltage shifting layer 208 can be altered by altering an amount of metal, nitrogen, carbon, oxygen and/or other constituents in the layer or in a deposition cycle.

In an example, threshold voltage shifting layer 208 can include impurities, such as halides, hydrogen, and/or oxygen or the like in an amount of less than ten atomic percent, five atomic percent, less than one atomic percent, less than 0.2 atomic percent, less than 0.1 atomic percent, or less than 0.05 atomic percent, alone or combined.

A thickness of threshold voltage shifting layer 208 can vary according to application. By way of example, a desired or predetermined thickness of threshold voltage shifting layer 208 can be less than 10 nm or about 0.05 nm to about 10 nm, or about 0.06 nm to about 5 nm, or about 0.07 nm to about 5 nm, or about 0.08 nm to about 4 nm, or about 0.09 nm to about 3 nm, or about 0.1 nm to about 2 nm. In an example, threshold voltage shifting layer 208 may be relatively thin, which may be desirable for many applications, including barrier layers, liners, and as work function layers. In an example, threshold voltage shifting layer 208 may form a non-continuous functional layer operable to perform voltage threshold adjustment. In some cases, a thickness of threshold voltage shifting layer 208 can be greater than 2 nm—e.g., when threshold voltage shifting layer 208 is used as a barrier layer or liner.

A thickness and/or composition of threshold voltage shifting layer 208 can be manipulated to obtain a desired shift in work function and/or threshold voltage. In an example, a work function of a shifted threshold voltage shifting layer 208 may be >4.6 eV, >4.7 eV, >4.8 eV, >4.9 eV, >4.95 eV, or >5.0 eV. A work function value of a device can be shifted by about 30 meV to about 400 meV, or about 30 meV to about 200 meV, or about 50 meV to about 100 meV using a threshold voltage shifting layer 208 as described herein.

Additionally or alternatively, threshold voltage shifting layer 208 can form a continuous film—e.g., using process 100—at a thickness of <5 nm, <4 nm, <3 nm, <2 nm, <1.5 nm, <1.2 nm, <1.0 nm, or <0.9 nm. threshold voltage shifting layer 208 can be relatively smooth, with relatively low grain boundary formation.

In some cases, threshold voltage shifting layer 208 can additionally or alternatively be formed directly over substrate 202 underlying dielectric or insulating material 205 (which can include various layers and/or topologies) as illustrated in FIG. 2B in accordance with additional examples of the disclosure. Device or structure 220 includes a substrate 202, dielectric or insulating material 205 including interface layer 204 and a high-k material 206 deposited overlying interface layer 204. Structure 220 also includes an additional conducting layer 210. Interface layer 204 is deposited overlying threshold voltage shifting layer 208.

In some cases, threshold voltage shifting layer 208 can additionally or alternatively be formed, between interface layer 204 and high-k material 206, and/or between layers of high-k material 206 as illustrated in FIG. 2C in accordance with additional examples of the disclosure. FIG. 2C is similar to the structure shown in FIG. 2A and 2B except that the threshold voltage shifting layer 208 is situated between the interface layer 204 and the high-k material 206. Threshold voltage shifting layer 208 is deposited in a dipole first pattern directly onto the interface layer 204 surface.

Device or structure 230 includes a substrate 202, threshold voltage shifting layer 208 is deposited directly on interface layer 204 and a high-k material 206 is deposited overlying threshold voltage shifting layer 208. Structure 230 also includes an additional conducting layer 210. Further, threshold voltage shifting layer 208 may be deposited and at least partially removed, such that resultant structures may no longer include threshold voltage shifting layer 208 or include a lesser number of metal layers than were initially formed on the structure.

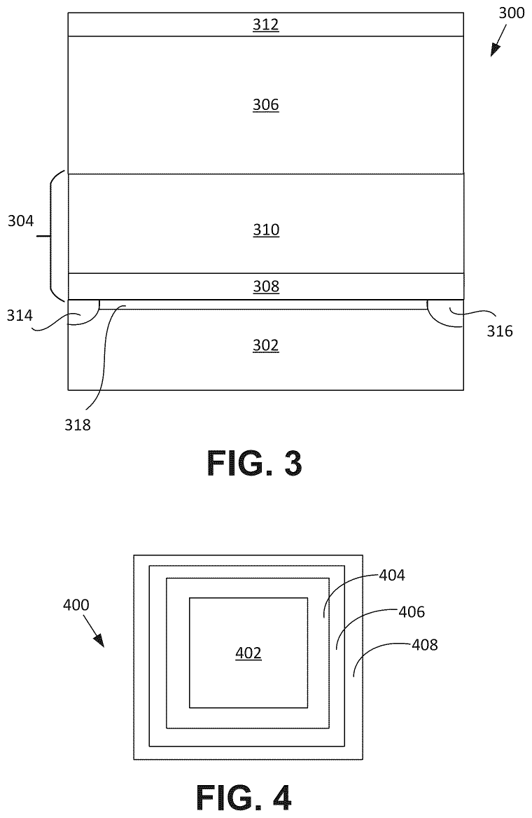

FIG. 3 illustrates another exemplary structure 300 in accordance with examples of the disclosure. Device or structure 300 includes a substrate 302, dielectric or insulating material 304, and threshold voltage shifting layer 306. In an example and as discussed in greater detail hereinabove, the threshold voltage shifting layer 306 may comprise a metal and is represented by the formula M(NxCyOz), wherein M is a metal, N is nitrogen, C is carbon, and O is oxygen, wherein x=0 to 5, y=0 to 5, z=0 to (x+y), wherein (x+y)≥0.1. In some examples, (x+y)>0. In some examples, (x+y)≥0. In some examples, (x+y)≥1. In some examples, x=0 to 2 and y=0 to 2. In some examples, threshold voltage shifting layer 306 is oxygen-free or substantially oxygen-free. In the illustrated example, structure 300 also includes an additional conducting layer 312. Substrate 302, dielectric or insulating material 304, threshold voltage shifting layer 306, and an additional conducting layer 312 can be the same or similar to substrate 202, dielectric or insulating material 205, threshold voltage shifting layer 208 and conducting layer 210. As in above, threshold voltage shifting layer 306 can additionally or alternatively be formed overlying substrate 302 (which can include various layers and/or topologies) and/or underlying insulating material 304, between interface layer 308 and high-k material 310. In an example, threshold voltage shifting layer 306 may be deposited in a dipole first scheme directly onto the interface layer 308 surface. In another example, threshold voltage shifting layer 306 may be deposited between layers of high-k material 310. Further, threshold voltage shifting layer 306 may be deposited and at least partially removed, such that resultant structures may no longer include threshold voltage shifting layer 306 or include a lesser number of threshold voltage shifting layers than were initially formed on the structure.

In the illustrated example, substrate 302 includes a source region 314, a drain region 316, and a channel region 318. Although illustrated as a horizontal structure, structures and devices in accordance with examples of the disclosure can include vertical and/or three-dimensional structures and devices, such as FinFET devices.

FIG. 4 illustrates another structure 400 in accordance with examples of the disclosure. Structure 400 is suitable for gate all around field effect transistors (GAA FET) (also referred to as lateral nanowire FET) devices and the like.

In the illustrated example, structure 400 includes semiconductor material 402, dielectric material 404, a threshold voltage shifting layer 406, and a conducting layer 408. Structure 400 can be formed overlying a substrate, including any substrate materials described herein. As discussed in greater detail hereinabove, threshold voltage shifting layer 406 may comprise a metal represented by the formula M(NxCyOz), wherein M is a metal, N is nitrogen, C is carbon, and O is oxygen, wherein x=0 to 5, y=0 to 5, z=0 to (x+y), wherein (x+y)≥0.1. In some embodiments, (x+y)>0. In some examples, (x+y)≥0. In some examples, (x+y)≥1. In some examples, x=0 to 2 and y=0 to 2. In some examples, threshold voltage shifting layer 408 is oxygen-free or substantially oxygen-free.

Semiconductor material 402 can include any suitable semiconducting material. For example, semiconductor material 402 can include Group IV, Group III-V, or Group II-VI semiconductor material. By way of example, semiconductor material 402 includes silicon.

Dielectric material 404, threshold voltage shifting layer 406, and conducting layer 408 can be the same or similar to dielectric or insulating material 205, threshold voltage shifting layer 208 and conducting layer 210, described above. Threshold voltage shifting layer 406 can be formed overlying semiconductor material 402 and/or underlying dielectric material 404 in accordance with further examples of the disclosure.

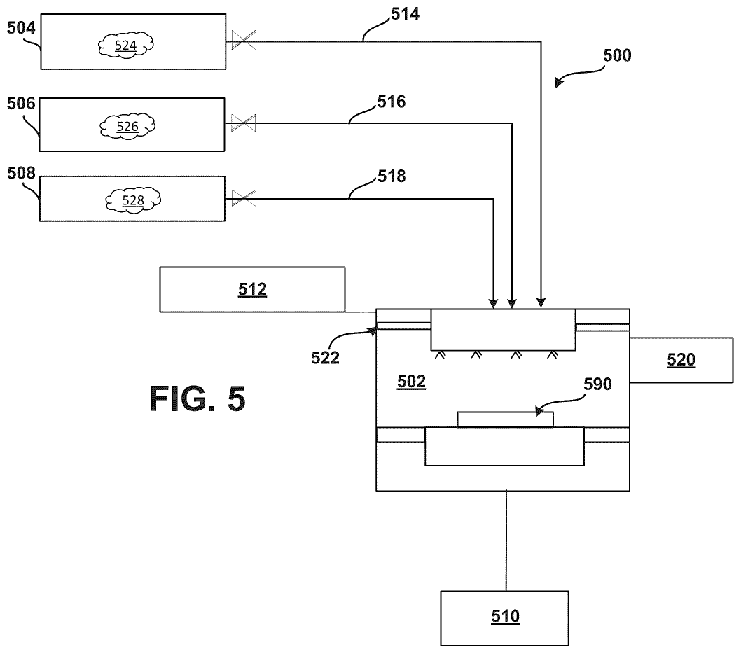

FIG. 5 illustrates a system 500 in accordance with yet additional exemplary embodiments of the disclosure. System 500 can be used to perform a method as described herein and/or form a structure or device portion as described herein.

In the illustrated example, system 500 includes one or more reaction chambers 502, a metal-containing precursor gas source 504, an additional precursor gas source 506, a purge gas source 508, an exhaust source 510, and a controller 512.

In examples, reaction chamber 502 can include any suitable reaction chamber, such as an ALD or CVD reaction chamber and may include a direct plasma source 522 or be coupled to a remote plasma source 520.

In an example, metal-containing precursor gas source 504 can include a vessel and one or more metal-containing precursors 524 as described herein-alone or mixed with one or more carrier (e.g., inert) gases. Metal-containing precursors 524 may be oxygen-free or substantially oxygen-free. The term “carrier gas” as used herein may refer to a gas that is provided to a reactor chamber together with one or more precursors. For example, a carrier gas may be provided to the reactor chamber together with one or more of the precursors used herein. Exemplary carrier gases include N₂, H₂, and noble gases such as He, Ne, Kr, Ar, and Xe.

In an example, additional precursor gas source 506 can include a vessel and one or more additional precursors 526 as described herein—alone or mixed with one or more carrier gases. The one or more additional precursors 526 may be oxygen-free or substantially oxygen-free.

In an example, purge gas source 508 can include one or more inert gases 528 as described herein. Although illustrated with three sources 504-508, system 500 can include any suitable number of gas sources. Sources 504-508 can be coupled to reaction chamber 502 via lines 514-518, which can each include flow controllers, valves, heaters, and the like. As used herein “oxygen-free” or “substantially oxygen-free” can refer to a precursor that is oxygen-free or substantially oxygen-free comprising less than about 7% oxygen, or less than about 5% oxygen, or less than about 4% oxygen, or less than about 3% oxygen, or less than about 2% oxygen, or less than about 1% oxygen, or less than about 0.1% oxygen, (“about” in this context means plus or minus 0.05%).

Exhaust source 510 can include one or more vacuum pumps.

Controller 512 includes electronic circuitry and software to selectively operate valves, manifolds, heaters, pumps and other components included in system 500. Such circuitry and components operate to introduce precursors, reactants, and purge gases from the respective sources 504-508. Controller 512 can control timing of gas pulse sequences, temperature of the substrate and/or reaction chamber, pressure within the reaction chamber, and various other operations to provide proper operation of system 500. Controller 512 can include control software to electrically or pneumatically control valves to control flow of precursors, reactants and purge gases into and out of reaction chamber 502. Controller 512 can include modules such as a software or hardware component, e.g., a FPGA or ASIC, which performs certain tasks. A module can advantageously be configured to reside on the addressable storage medium of the control system and be configured to execute one or more processes (e.g., process 100 illustrated in FIG. 1).

Other configurations of system 500 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 502. Further, as a schematic representation of a system, many components have been omitted for simplicity of illustration, and such components may include, for example, various valves, manifolds, purifiers, heaters, containers, vents, and/or bypasses.

During operation of reactor system 500, substrates 590, such as semiconductor wafers, are transferred from, e.g., a substrate handling system to reaction chamber 502. Once substrate(s) are transferred to reaction chamber 502, one or more gases from sources 504-508, such as precursors, reactants, carrier gases, and/or purge gases, are introduced into reaction chamber 502, for example, during execution of process 100 illustrated in FIG. 1.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims. Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

1. A method comprising:
depositing a threshold voltage shifting layer on a substrate, wherein the layer comprises a metal and has the formula M(NxCyOz), wherein M is a metal, N is nitrogen, C is carbon, and O is oxygen, wherein x=0 to 5, y=0 to 5, z=0 to (x+y), wherein (x+y)≥0.1, wherein depositing the threshold voltage shifting layer further comprises:
a) providing the substrate having a surface within a reaction chamber;
b) providing a metal-containing precursor comprising the metal to the reaction chamber to contact the surface;
c) providing one or more additional precursors comprising at least one of N or C to the reaction chamber to contact the surface;
d) purging the reaction chamber; and
repeating operations b), c) or d) or any combination thereof in any order until the threshold voltage shifting layer of a predetermined thickness is deposited on the surface.

2. The method of claim 1, wherein x=0 to 2 and y=0 to 2.

3. The method of claim 1, wherein (x+y)≥1.

4. The method of claim 1, wherein at least one of the one or more additional precursors comprises O.

5. The method of claim 1, wherein the surface comprises an interlayer material and the threshold voltage shifting layer is deposited in a dipole first pattern directly onto the interlayer material surface.

6. The method of claim 1, wherein the surface comprises a high-k material and the threshold voltage shifting layer is deposited in a dipole last pattern directly onto the high-k material surface.

7. The method of claim 1, wherein the metal comprises cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), titanium (Ti), zirconium (Zr), hafnium (Hf), tantalum (Ta), scandium (Sc), lutetium (Lu), yttrium (Y), magnesium (Mg), lanthanum (La), or strontium (Sr), or a combination thereof.

8. The method of claim 7, wherein the metal-containing precursor comprises a cyclopentadienyl ligand.

9. The method of claim 8, wherein the cyclopentadienyl ligand comprises at least one of cyclopentadienyl (Cp), methylcyclopentadienyl (MeCp), ethylcyclopentadienyl (EtCp), isopropylcyclopentadienyl (iPrCp), tert-butylcyclopentadienyl (tBuCp), trimethylsilylcyclopentadienyl (TMSCp), pentamethylcyclopentadientyl (Cp*), 1,2,4-triisopropylcyclopentadienyl (iPr₃Cp), and 1,2,4-tri-tert-butylcyclopentadienyl (tBu₃Cp).

10. The method of claim 7, wherein the metal-containing precursor comprises an amido ligand.

11. The method of claim 10, wherein the amido ligand comprises at least one of dimethylamido (NMe₂), diethylamido (NEt₂), ethylmethylamido (NEtMe), diisopropylamido (NiPr₂), tert-butylamino (NHtBu), and bis(trimethylsilyl)amido (N(SiMe₃)₂).

12. The method of claim 7, wherein the metal-containing precursor comprises an imido ligand.

13. The method of claim 12, wherein the imido ligand comprises at least one of ethylimido (NEt), isoproptylimido (NiPr), isobutylimido (NiBu), tert-butylimido (NtBu), and tert-pentylimido (NtPn).

14. The method of claim 7, wherein the metal-containing precursor comprises an amidinate ligand.

15. The method of claim 14, wherein the amidinate ligand comprises at least one of N,N′-diethylacetamidinate (Et₂AMD), N,N′-diisopropylacetamidinate (iPr₂AMD), N,N′-diisopropylformamidinate (iPr₂FMD), N,N′-di-tert-butylacetamidinate (tBu₂AMD), and N,N′-di-tert-butylformamidinate (tBu₂FMD).

16. The method of claim 7, wherein the metal-containing precursor comprises a halogen ligand.

17. The method of claim 16, wherein the halogen ligand comprises, at least one of (F) fluorine, (Cl) chlorine, (Br) bromine or (I) iodine.

18. The method of claim 7, wherein the metal-containing precursor comprises an alkyl ligand.

19. The method of claim 18, wherein the alkyl ligand comprises, at least one of methyl (Me), ethyl (Et), isopropyl (iPr), tert-butyl (tBu), isobutyl (iBu), and neopentyl (Np).

20. The method of claim 7, wherein the metal-containing precursor comprises an alkoxide ligand.

21. The method of claim 20, wherein the alkoxide ligand comprises, at least one of methoxide (OMe), ethoxide (OEt), isopropoxide (OiPr), tert-butoxide (OtBu), 1-methoxy-2-methyl-2-propoxide (mmp), 1-dimethylamino-2-propoxide (dmap), 1-dimethylamino-2-methyl-2-propoxide (dmamp), and 1-dimethylamino-2-methyl-2-butoxide (dmamb).

22. The method of claim 7, wherein the metal-containing precursor comprises a diketonate ligand.

23. The method of claim 22, wherein the diketonate ligand comprises, at least one of acetylacetonate (acac), 2,2,6,6-tetramethylheptane-3,5-dionate (thd), and 1,1,1,5,5,5-hexafluoropentane-2,5-dionate (hfac).

24. The method of claim 7, wherein the metal-containing precursor comprises a diazabutadiene ligand.

25. The method of claim 24, wherein the diazabutadiene ligand comprises, at least one of 1,4-di-tert-butyl-1,4-diaza-1,3-butadiene (tBu₂DAD), 1,4-diisopropyl-1,4-diaza-1,3-butadiene (iPr₂DAD), 1,4-di-sec-butyl-1,4-diaza-1,3-butadiene (sBu₂DAD) and 1,4-di-tert-pentyl-1,4-diaza-1,3-butadiene (tPn₂DAD).

26. The method of claim 1, wherein at least one of the one or more additional precursors is a nitrogen-containing precursor.

27. The method of claim 26, wherein the nitrogen-containing precursor is selected from:
ammonia, hydrazine, tert-butylhydrazine, dimethylhydrazine, methylhydrazine, phenylhydrazine, tert-butylamine, isobutylamine, tert-pentylamine, N₂ plasma, NH₃ plasma, or N₂/H₂ plasma, or any combination thereof.

28. The method of claim 1, wherein at least one of the one or more additional precursors is a carbon-containing precursor.

29. The method of claim 28, wherein the carbon-containing precursor is selected from:
iodomethane, diiodomethane, iodoethane, 1,2-diiodoethane, bromoethane, 1,2-dibromoethane, bromobenzene, iodobenzene, 1-iodobutane, dicyclopentadiene, acetylene, propargyl bromide, allyl bromide, or allyl iodide, or a combination thereof.

30. The method of claim 1, wherein at least one of the one or more additional precursors is an oxygen-containing precursor.

31. The method of claim 30, wherein the oxygen-containing precursor is selected from: H₂O, ozone, N₂O, H₂O₂, O₂, or O₂ plasma, or any combination thereof.

32. The method of claim 1, wherein the metal comprises titanium (Ti) and wherein the metal-containing precursor comprises TiF₄, TiCl₄, TiBr₄, TiI₄, Ti(NMe₂)₄, Ti(NEtMe)₄, Ti(NEt₂)₄, Ti(OMe)₄, Ti(OEt)₄, Ti(OiPr)₄, Ti(OtBu)₄, Ti(MeCp)(OiPr)₃, TiCp*(OMe)₃, TiCp(NMe₂)₄, Ti(EtCp)(NMe₂)₄, Ti(OiPr)₂(NMe₂)₂, Ti(OiPr)₂(thd)₂, Ti(OiPr)₃(iPr₂AMD), or Ti(Np)₄, or a combination thereof.

33. The method of claim 1, wherein the metal comprises zirconium (Zr) and wherein the metal-containing precursor comprises ZrCl₄, ZrI₄, Zr(NMe₂)₄, Zr(NEtMe)₄, Zr(NEt₂)₄, Zr(thd)₄, Zr(OiPr)₄, Zr(OtBu)₄, ZrCp(NMe₂)₃, Zr(MeCp)(NMe₂)₃, Zr(EtCp)(NMe₂)₃, ZrCp(NEt₂)₃, Zr(MeCp)(NEt₂)₃, Zr(EtCp)(NEt₂)₃, ZrCp(NEtMe)₃, Zr(MeCp)(NEtMe)₃, Zr(EtCp)(NEtMe)₃, ZrCp₂Cl₂, ZrCp₂Me₂, ZrCp₂(OMe)₂, ZrCp₂Me(OMe), ZrCp₂(NMe₂)₂, Zr(MeCp)₂Cl₂, Zr(MeCp)₂Me₂, Zr(MeCp)₂(OMe)₂, Zr(MeCp)₂Me(OMe), Zr(MeCp)₂(NMe₂)₂, Zr(EtCp)₂Cl₂, Zr(EtCp)₂Me₂, Zr(EtCp)₂(OMe)₂, Zr(EtCp)₂Me(OMe), Zr(EtCp)₂(NMe₂)₂, ZrNp₄, or ZrCp(tBu₂DAD)(OiPr), or any combination thereof.

34. The method of claim 1, wherein the metal comprises hafnium (Hf) and wherein the metal-containing precursor comprises HfCl₄, HfI₄, Hf(NMe₂)₄, Hf(NEtMe)₄, Hf(NEt₂)₄, Hf(thd)₄, Hf(OiPr)₄, Hf(OtBu)₄, Hf(BH₄)₄, HfCp(NMe₂)₃, Hf(MeCp)(NMe₂)₃, Hf(EtCp)(NMe₂)₃, HfCp(NEt₂)₃, Hf(MeCp)(NEt₂)₃, Hf(EtCp)(NEt₂)₃, HfCp(NEtMe)₃, Hf(MeCp)(NEtMe)₃, Hf(EtCp)(NEtMe)₃, HfCp₂Cl₂, HfCp₂Me₂, HfCp₂(OMe)₂, HfCp₂Me(OMe), HfCp₂(NMe₂)₂, Hf(MeCp)₂Cl₂, Hf(MeCp)₂Me₂, Hf(MeCp)₂(OMe)₂, Hf(MeCp)₂Me(OMe), Hf(MeCp)₂(NMe₂)₂, Hf(EtCp)₂Cl₂, Hf(EtCp)₂Me₂, Hf(EtCp)₂(OMe)₂, Hf(EtCp)₂Me(OMe), Hf(EtCp)₂(NMe₂)₂, Hf(MeCp)₂(mmp)Me, Hf(OtBu)₂(mmp)₂, Hf(iPr₂FMD)₂(NMe₂)₂, HfNp₄, Hf(dmap)₄, or Hf(mmp)₄, or any combination thereof.

35. The method of claim 1, wherein the metal comprises tantalum (Ta) and wherein the metal-containing precursor comprises TaF₅, TaCl₅, TaBr₅, TaI₅, Ta(NMe₂)₅, Ta(NEt₂)₅, Ta(NEtMe)₅, Ta(NtBu)(NMe₂)₃, Ta(NtBu)(NEt₂)₃, Ta(NtBu)(NEtMe)₃, Ta(NiPr)(NEtMe)₃, Ta(NtPn)(NMe₂)₃, Ta(OEt)₅, TaNp₃Cl₂, Ta(NtBu) Cl₃, Ta(NtPn) Cl₃, or Ta(NtBu)(iPr₂AMD)₂(NMe₂), or any combination thereof.

36. The method of claim 1, wherein the metal comprises scandium (Sc) and wherein the metal-containing precursor comprises ScCp₃, Sc(MeCp)₃, Sc(EtCp)₃, Sc(iPrCp)₃, Sc(acac)₃, Sc(thd)₃, Sc(N(SiMe₃)₂)₃, Sc(Et₂AMD)₃, Sc(iPr₂FMD)₃, Sc(iPr₂AMD)₃, Sc(tBu₂FMD)₃, Sc(tBu₂AMD)₃, ScCp₂(iPr₂FMD), Sc(MeCp)₂(iPr₂FMD), Sc(EtCp)₂(iPr₂FMD), Sc(iPrCp)₂(iPr₂FMD), ScCp₂(iPr₂AMD), Sc(MeCp)₂(iPr₂AMD), Sc(EtCp)₂(iPr₂AMD), or Sc(iPrCp)₂(iPr₂AMD), or any combination thereof.

37. The method of claim 1, wherein the metal comprises lutetium (Lu) and wherein the metal-containing precursor comprises LuCp₃, Lu(MeCp)₃, Lu(EtCp)₃, Lu(iPrCp)₃, Lu(acac)₃, Lu(thd)₃, Lu(OiPr)₃, Lu(OtBu)₃, Lu(N(SiMe₃)₂)₃, Lu(Et₂FMD)₃, Lu(iPr₂FMD)₃, Lu(tBu₂FMD)₃, Lu(iPr₂AMD)₃, Lu(tBu₂AMD)₃, LuCp₂(iPr₂FMD), Lu(MeCp)₂(iPr₂FMD), Lu(EtCp)₂(iPr₂FMD), Lu(iPrCp)₂(iPr₂FMD), LuCp₂(iPr₂AMD), Lu(MeCp)₂(iPr₂AMD), Lu(EtCp)₂(iPr₂AMD), or Lu(iPrCp)₂(iPr₂AMD), or any combination thereof.

38. The method of claim 1, wherein the metal comprises magnesium (Mg) and wherein the metal-containing precursor comprises Mg(acac)₂, Mg(hfac)₂, Mg(thd)₂, MgCp₂, Mg(MeCp)₂, Mg(EtCp)₂, Mg(iPr₂AMD)₂, Mg(sBu₂AMD)₂, Mg(tBu₂AMD)₂, Mg(iPr₂DAD)₂, Mg(tBu₂DAD)₂, or Mg(sBu₂DAD)₂, or any combination thereof.

39. The method of claim 1, wherein the metal comprises lanthanum (La) and wherein the metal-containing precursor comprises LaCp₃, La(MeCp)₃, La(EtCp)₃, La(iPrCp)₃, La(tBuCp)₃, La(TMSCp)₃, La(thd)₃, La(N(SiMe₃)₂)₃, La(iPr₂FMD)₃, La(tBu₂FMD)₃, La(sBu₂FMD)₃, La(tPn₂FMD)₃, La(iPr₂AMD)₃, La(tBu₂AMD)₃, La(sBu₂AMD)₃, La(tPn₂AMD)₃, LaCp₂(iPr₂AMD), LaCp₂(tBu₂AMD), LaCp₂(iPr₂FMD), LaCp₂(tBu₂FMD), La(MeCp)₂(iPr₂AMD), La(MeCp)₂(tBu₂AMD), La(MeCp)₂(iPr₂FMD), La(MeCp)₂(tBu₂FMD), La(EtCp)₂(iPr₂AMD), La(EtCp)₂(tBu₂AMD), La(EtCp)₂(iPr₂FMD), La(EtCp)₂(tBu₂FMD), La(iPrCp)₂(iPr₂AMD), La(iPrCp)₂(tBu₂AMD), La(iPrCp)₂(iPr₂FMD), La(iPrCp)₂(tBu₂FMD), La(tBuCp)₂(iPr₂AMD), La(tBuCp)₂(tBu₂AMD), La(tBuCp)₂(iPr₂FMD), or La(tBuCp)₂(tBu₂FMD), or any combination thereof.

40. The method of claim 1, wherein the metal-containing precursor comprises at least one of the following KCp₃, K(MeCp)₃, K(EtCp)₃, K(iPrCp)₃, K(tBuCp)₃, K(TMSCp)₃, K(thd)₃, K(N(SiMe₃)₂)₃, K(iPr₂FMD)₃, K(tBu₂FMD)₃, K(sBu₂FMD)₃, K(tPn₂FMD)₃, K(iPr₂AMD)₃, K(tBu₂AMD)₃, K(sBu₂AMD)₃, K(tPn₂AMD)₃, KCp₂(iPr₂AMD), KCp₂(tBu₂AMD), KCp₂(iPr₂FMD), KCp₂(tBu₂FMD), K(MeCp)₂(iPr₂AMD), K(MeCp)₂(tBu₂AMD), K(MeCp)₂(iPr₂FMD), K(MeCp)₂(tBu₂FMD), K(EtCp)₂(iPr₂AMD), K(EtCp)₂(tBu₂AMD), K(EtCp)₂(iPr₂FMD), K(EtCp)₂(tBu₂FMD), K(iPrCp)₂(iPr₂AMD), K(iPrCp)₂(tBu₂AMD), K(iPrCp)₂(iPr₂FMD), K(iPrCp)₂(tBu₂FMD), K(tBuCp)₂(iPr₂AMD), K(tBuCp)₂(tBu₂AMD), K(tBuCp)₂(iPr₂FMD), or K(tBuCp)₂(tBu₂FMD), or any combination thereof, wherein K is the metal selected from the group comprising cerium (Ce), praseodymium (Pr), neodymium (Nd), samarium (Sm), europium (Eu), gadolinium (Gd), terbium (Tb), dysprosium (Dy) or lanthanum (La).

41. The method of claim 1, wherein the metal comprises yttrium (Y) and wherein the metal precursor comprises YCp₃, Y(MeCp)₃, Y(EtCp)₃, Y(iPrCp)₃, Y(tBuCp)₃, Y(thd)₃, Y(N(SiMe₃)₂)₃, Y(tBu₂FMD)₃, Y(tBu₂AMD)₃, Y(iPr₂FMD)₃, Y(iPr₂AMD)₃, YCp₂(iPr₂AMD), YCp₂(tBu₂AMD), YCp₂(iPr₂FMD), YCp₂(tBu₂FMD), Y(MeCp)₂(iPr₂AMD), Y(MeCp)₂(tBu₂AMD), Y(MeCp)₂(iPr₂FMD), Y(MeCp)₂(tBu₂FMD), Y(EtCp)₂(iPr₂AMD), Y(EtCp)₂(tBu₂AMD), Y(EtCp)₂(iPr₂FMD), Y(EtCp)₂(tBu₂FMD), Y(iPrCp)₂(iPr₂AMD), Y(iPrCp)₂(tBu₂AMD), Y(iPrCp)₂(iPr₂FMD), or Y(iPrCp)₂(tBu₂FMD), or any combination thereof.

42. The method of claim 1, wherein the metal-containing precursor comprises at least one of the following JCp₃, J(MeCp)₃, J(EtCp)₃, J(iPrCp)₃, J(tBuCp)₃, J(thd)₃, J(N(SiMe₃)₂)₃, J(tBu₂FMD)₃, J(tBu₂AMD)₃, J(iPr₂FMD)₃, J(iPr₂AMD)₃, JCp₂(iPr₂AMD), JCp₂(tBu₂AMD), JCp₂(iPr₂FMD), JCp₂(tBu₂FMD), J(MeCp)₂(iPr₂AMD), J(MeCp)₂(tBu₂AMD), J(MeCp)₂(iPr₂FMD), J(MeCp)₂(tBu₂FMD), J(EtCp)₂(iPr₂AMD), J(EtCp)₂(tBu₂AMD), J(EtCp)₂(iPr₂FMD), J(EtCp)₂(tBu₂FMD), J(iPrCp)₂(iPr₂AMD), J(iPrCp)₂(tBu₂AMD), J(iPrCp)₂(iPr₂FMD), or J(iPrCp)₂(tBu₂FMD), or any combination thereof, where J is the metal selected from the group comprising holmium (Ho), erbium (Er), thulium (Tm), ytterbium (Yb) or yttrium (Y).
